(19) United States
(12) Patent Application Publication
(10) Pub. No.: US 2021/0208290 A1
(43) Pub. Date: Jul. 8, 2021

(54) PHOTODETECTOR CONFIGURATIONS

(71) Applicant: APPLIED MATERIALS ISRAEL LTD., Rehovot (IL)

(72) Inventor: Pavel Margulis, Ashdod (IL)

(73) Assignee: APPLIED MATERIALS ISRAEL LTD., Rehovot (IL)

(21) Appl. No.: 16/732,573

(22) Filed: Jan. 2, 2020

(51) Int. Cl. G01T 1/17; G01T 1/20; H01J 37/244; H01J 37/28

(52) U.S. Cl. CPC G01T 1/17; H01J 37/28; H01J 37/244; G01T 1/2018

(57) ABSTRACT

A device and method for detecting radiation comprising: a radiation-sensitive surface composed of an array of electrically inter-isolated radiation-sensitive elements (e.g. avalanche photodiode (APD), PIN diode, or scintillation sensor), each radiation-sensitive element is adapted to generate an electric current in response to absorbing radiation; an array of conversion circuits, each conversion circuit electrically coupled to a respective radiation-sensitive element and configured to generate an output signal indicative of the current generated by the radiation-sensitive element coupled thereto; and one or more summation arrangements, each summation arrangement coupled to a respective group of the conversion circuits, and configured to produce a summation result indicative of the radiation absorbed by respective group of the conversion circuits. The radiation-sensitive surface may be shaped as a dome-shape surface. The radiation-sensitive elements may be associated with radiation-sensitive planes such that all of the radiation-sensitive elements are directed toward a focal point on an inspected surface.

### FIELD OF THE INVENTION

The present invention relates generally to radiation sensitive detectors, and more particularly, to methods and systems for efficiently evaluating objects under test using radiation sensitive detectors.

### BACKGROUND OF THE INVENTION

Optical detectors, for example, composed of a photodiode followed by a transimpedance amplifier (TIA) are well known.

The performance of optical detectors is considerably affected by noise. Various techniques have heretofore been disclosed in the art in order to reduce the noise level at the TIA output. There is a need for improved techniques of employing radiation sensitive detectors.

### BRIEF SUMMARY OF THE INVENTION

According to embodiments of the invention, there is provided a device for detecting radiation comprising: a radiation-sensitive surface composed of an array of electrically inter-isolated radiation-sensitive elements, each radiation-sensitive element is adapted to generate an electric current in response to absorbing radiation; an array of conversion circuits, each conversion circuit electrically coupled to a respective radiation-sensitive element and configured to generate an output signal indicative of the current generated by the radiation-sensitive element coupled thereto; and one or more summation arrangements, each summation arrangement coupled to a respective group of the conversion circuits, and configured to produce a summation result indicative of the radiation absorbed by respective group of the conversion circuits.

The radiation-sensitive elements may be formed of one or more of a group consisting of: avalanche photodiodes (APDs), PIN diodes, and scintillation sensors.

Each conversion circuit may comprise a transimpedance amplifier.

The summation arrangement may comprise a digital processing unit.

The device may be arranged with one or more openings configured for allowing radiation to pass through the one or more openings.

The radiation-sensitive surface may be shaped as a dome-shape surface.

Different radiation-sensitive elements may be associated with different radiation-sensitive planes such that all of the radiation-sensitive elements are directed toward a focal point on an inspected surface, an angle between a normal to a radiation-sensitive plane and the inspected surface is inversely proportional to the length of said normal, and the shortest distance between each radiation-sensitive plane and the inspected surface is equal to or greater than a preconfigured minimum working distance.

The radiation-sensitive segment may further be composed of a support arrangement to which the radiation-sensitive elements are mechanically attached and wherein the radiation-sensitive elements are arranged in one of the formats: adjacent to each other; spaced-apart from each other; and a combination thereof.

In accordance with an embodiment of the invention, a method for reducing noise in an inspection system is disclosed, comprising: irradiating an inspected surface with one or more electron beams; by a segmented radiation-sensitive surface composed of an array of electrically inter-isolated radiation-sensitive elements, detecting resulting radiation emanating from the inspected surface in response to the irradiating; converting, by an array of conversion circuits, each conversion circuit electrically coupled to a respective radiation-sensitive element, the currents produced by the radiation-sensitive elements due to detecting the emanated radiation, to respective voltage signals; producing, by one or more summation arrangements, each summation arrangement coupled to a respective group of the conversion circuits, a summation result indicative of the radiation absorbed by respective group of the conversion circuits; and analyzing the radiation detected by the segmented radiation-sensitive surface according to the resulting summation signal.

In accordance with an embodiment of the present invention, a radiation-sensitive system is disclosed comprising: An array of electrically inter-isolated radiation-sensitive elements forming a radiation-sensitive surface, wherein each radiation-sensitive element is adapted to generate an electric current in response to absorbing radiation; an array of conversion circuits, each conversion circuit electrically coupled to a respective radiation-sensitive element and configured to generate an output signal indicative of the current generated by the radiation-sensitive element coupled to said conversion circuit; and at least one summation arrangement coupled to a group of the conversion circuits, wherein the conversion circuits that belong to said group are electrically coupled to radiation-sensitive elements that constitute a contiguous segment of the radiation-sensitive surface comprising at least part of the array of radiation-sensitive elements, said summation arrangement configured to produce a summation result indicative of the whole radiation absorbed by said segment of the radiation-sensitive surface.

In some embodiments, the radiation-sensitive surface comprises an opening that allows a primary radiation beam to pass through and irradiate an inspected surface. Resulting radiation emanated from the inspected surface is then detected by the radiation-sensitive surface. In some of these embodiments, this technique is employed in various evaluation applications such as defect detection, defect review and critical dimension inspection in semiconductor wafers and in masks for manufacturing semiconductor wafers.

In some embodiments, the radiation-sensitive surface comprises an arrangement of individually cut sections, wherein a collection of section sides, one of each section, forms an opening in the radiation-sensitive surface having either a partial or a complete polygon shape.

In some embodiments, the conversion circuits comprise transimpedance amplifiers.

In some embodiments, the radiation-sensitive elements are mechanically attached to a support arrangement, e.g. a ceramic substrate such that all the elements are directed to a common focal point on an inspected surface, an angle between the normal to a radiation-sensitive plane and the inspected surface is inversely related to the length of said normal to the radiation-sensitive plane, and the shortest distance between each radiation-sensitive plane and the inspected surface is equal to or greater than a preconfigured minimum working distance.

In accordance with an embodiment of the present invention, there is also provided a method for reducing noise in an object evaluation system. The method comprises the steps of: irradiating an object under evaluation, detecting by several adjacent electrically inter-isolated radiation-sensitive elements the radiation emanating from the object due to the irradiation, converting currents generated in response to the detection to respective voltage signals, and summing the voltage signals.

In accordance with an embodiment of the present invention, there is also provided a radiation-sensitive device comprising radiation-sensitive elements that are mechanically attached to a support arrangement, e.g. a ceramic substrate such that all the elements are directed to a common focal point on an inspected surface, an angle between the normal to a radiation-sensitive plane and the inspected surface is inversely related to the length of said normal to the radiation-sensitive plane, and the shortest distance between each radiation-sensitive plane and the inspected surface is equal to or greater than a preconfigured minimum working distance.

In some embodiments, there is at least one traversing opening in the radiation-sensitive device. In some of these embodiments, the at least one traversing opening is formed to allow radiation to pass therethrough toward the focal point, thereby allowing a responsive radiation to emanate therefrom toward the radiation-sensitive elements. In some of these embodiments, this technique is employed in various evaluation applications such as defect detection, defect review and critical dimension inspection in semiconductor wafers and in masks for manufacturing semiconductor wafers.

In some embodiments some of the radiation-sensitive element in the device is electrically coupled to a respective conversion circuit, said respective conversion circuit configured to generate an output signal indicative of the electrical current generated by the radiation-sensitive element coupled to the respective conversion circuit, and there is at least one segment of the radiation-sensitive device comprising at least part of the radiation-sensitive elements, wherein all the output signals resulting from the radiation-sensitive elements comprised in said segment are conveyed to a summation arrangement configured to produce a summation result indicative of the whole radiation absorbed by said segment of the radiation-sensitive device. In some of these embodiments, the conversion circuits comprise transimpedance amplifiers.

In some embodiments, the radiation-sensitive device comprises an arrangement of individually cut sections, wherein a collection of section sides, one of each section, forms an opening in the radiation-sensitive surface having either a partial or a complete polygon shape.

In accordance with an embodiment of the present invention, there is also provided an arrangement of individually cut radiation-sensitive sections arranged to form a radiation-sensitive surface, wherein a group of section sides, one of each section, form an opening in the radiation-sensitive surface having either a partial or a complete polygon shape.

In some embodiments, the above opening is formed to allow radiation to pass therethrough toward an object under evaluation so as to result in radiation emanating from the object under evaluation toward the radiation-sensitive surface. In some of these embodiments, this technique is employed in various evaluation applications such as defect review and critical dimension inspection in semiconductor wafers and in masks for manufacturing semiconductor wafers.

In some embodiments, at least one of the radiation-sensitive sections comprises an array of electrically inter-isolated radiation-sensitive elements, each electrically coupled to a respective conversion circuit, said respective conversion circuit configured to generate an output signal indicative of the electrical current generated by the radiation-sensitive element coupled to the respective conversion circuit, and there is at least one segment of the array comprising at least part of the radiation-sensitive elements contained in the array, wherein all the output signals resulting from the radiation-sensitive elements comprised in said segment are conveyed to a summation arrangement configured to produce a summation result indicative of the whole radiation absorbed by said segment of the array. In some of these embodiments, the conversion circuits comprise transimpedance amplifiers.

In some embodiments, at least one of the radiation-sensitive sections comprises an array of electrically inter-isolated radiation-sensitive elements that are disposed to form an array of radiation-sensitive planes wherein each radiation-sensitive plane comprises one or more radiation-sensitive elements, said at least one of the radiation-sensitive sections further comprises a support arrangement to which the radiation-sensitive elements are mechanically attached, and wherein the support arrangement is structured such that all the radiation-sensitive elements are directed toward a focal point on an inspected surface, an angle between the normal to a radiation-sensitive plane and the inspected surface is inversely proportional to the length of said normal, and the shortest distance between each radiation-sensitive plane and the inspected surface is equal to or greater than a preconfigured minimum working distance. In some of these embodiments, this technique is employed in various evaluation applications such as defect review and critical dimension inspection in semiconductor wafers and in masks used for manufacturing semiconductor wafers.

In all the above embodiments, the involved radiation-sensitive devices and elements may comprise avalanche photodiodes (APDs), PIN diodes, or scintillation sensors. In some of these embodiments, the involved arrays may comprise radiation-sensitive elements of more than one type. For example, APD combined with a scintillator, or a PIN diode combined with a scintillator, can be used.

### BRIEF DESCRIPTION OF THE DRAWINGS

For a better understanding of the invention with regard to the embodiments thereof, reference is made to the accompanying drawings, in which like numerals designate corresponding entities throughout, and in which:

FIG. 1A is a block diagram that schematically illustrates a part of an inspection system, in accordance with an embodiment of the present invention;

FIG. 1B is a partial zoom out of the inspection system shown in FIG. 1A;

FIGS. 2A and 2B depict two views of a multiplane radiation-sensitive device, in accordance with an embodiment of the present invention;

FIG. 3A illustrates a multi-section radiation-sensitive device comprising a square opening, in accordance with an embodiment of the present invention;

FIG. 3B illustrates a multi-section radiation-sensitive device comprising an opening having a shape of a partial polygon, in accordance with an embodiment of the present invention; and

FIG. 4 is a flowchart that schematically illustrates a method for reducing noise in an inspection system, in accordance with an embodiment of the present invention.

### DETAILED DESCRIPTION OF THE INVENTION

Embodiments of the present invention provide new techniques that improve signal to noise ratio in inspection systems that employ optical detectors. Embodiments of the invention will be presented with respect to their use in inspection systems for evaluating semiconductor wafers and masks for manufacturing semiconductor dies, and in various related applications such as defect detection, defect review and critical dimension inspection. These techniques exploit inherent properties of photodetectors, such as capacitance-area relation and efficiency-‘incidence angle’ relation.

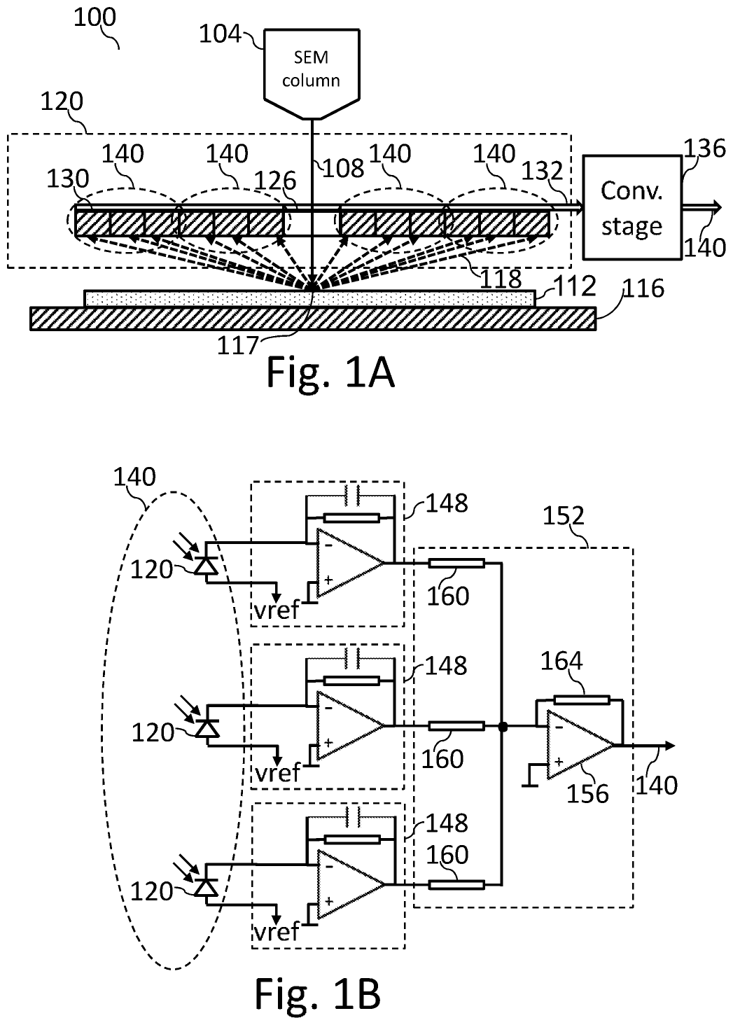

Referring to FIG. 1A there is shown a block diagram that schematically illustrates a part of a wafer inspection system 100, in accordance with an embodiment of the present invention. In FIG. 1A, a Scanning Electron Microscope (SEM), represented by a SEM column 104, emits a primary electron beam 108. In other embodiments, other beam sources may be employed, e.g. a laser emitting a single primary photon beam or multiple beams, an electron source emitting multiple beams.

Electron beam 108 impinges on an inspected surface 112 at an incidence point 117. In the described embodiment inspected surface 112 belongs to a semiconductor wafer, which is mounted on a stage 116. When the electrons in beam 108 penetrate the wafer they are scattered into an onion shaped volume. In this scattering process low energy electrons, so called secondary electrons or SE are generated. High energy electrons, so called backscattered electrons or BSE are also generated. A detection system (shown in part in FIG. 1A as device 120) collects the radiation that emanates from the volume around incidence point 117 (depicted in FIG. 1A by dashed arrows 118). The electrons 118 are detected by being absorbed by the radiation-sensitive surface (not specifically shown in FIG. 1A) of a radiation-sensitive device 120 which is shown in cross section view. In the middle of radiation-sensitive device 120, there is a traversing opening 126 that allows electron beam 108 to pass through radiation-sensitive device 120 toward semiconductor wafer 112.

Radiation-sensitive device 120 comprises of an array of adjacent electrically inter-isolated photodiode elements indicated by reference numeral 130 (only one numeral 130 is depicted in FIG. 1A for the sake of simplicity). In one embodiment, each element 130 comprises avalanche photodiode (APD). In other embodiments, other radiation-sensitive device types are employed such as PIN diode, and scintillation sensor. A combination of devices can be used. A combination of an APD or PIN diode with a scintillator can be used. When a scintillation sensor is employed, it can be coupled to any type of a radiation-sensitive device, including photomultiplier tube (PMT), either directly or through a light guide. While absorbing radiation 118, each element 130 generates an electric current approximately proportional to the radiation absorbed by the element. Conductive wires 132 convey the generated currents to a conversion stage 136 comprising an array of conversion circuits, one per each element 130. Conversion stage 136 is further described below. Conversion stage 136 then outputs, through an output 142, one or more voltage signals representing the above currents, for analysis and/or evaluation in a subsequent stage not shown in FIG. 1A.

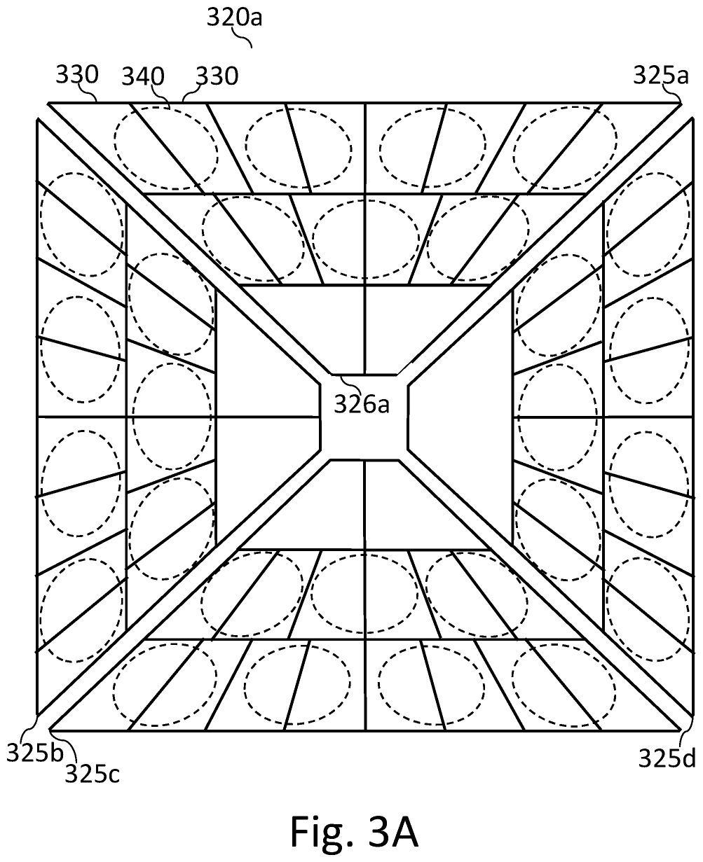

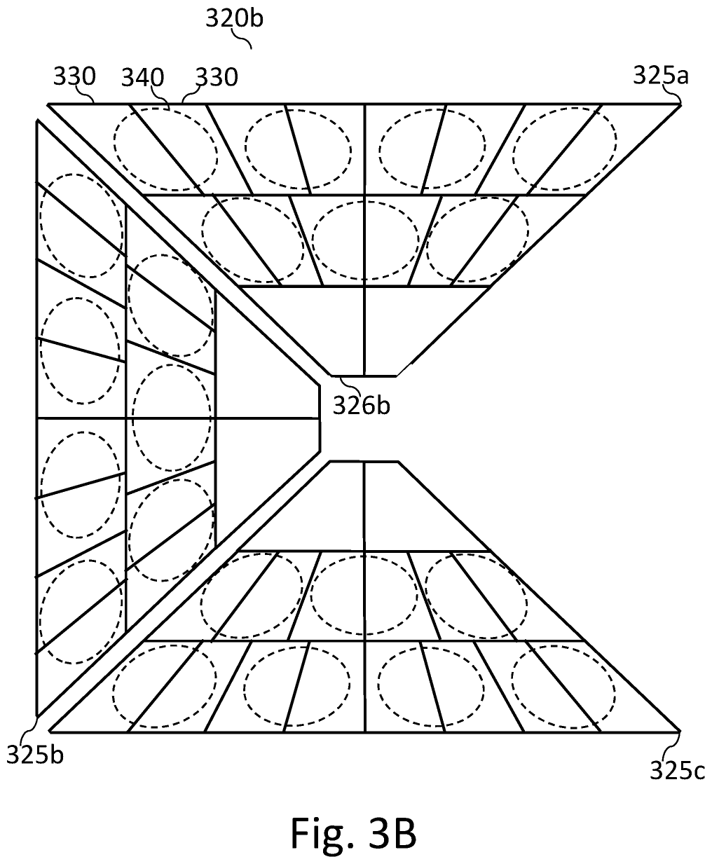

Radiation-sensitive device 120 is segmented such that each segment comprises a contiguous group of adjacent elements that are indicated by a dashed ellipse 140. In one embodiment, each segment 140 comprises three APD elements, as illustrated in FIG. 1A. However, this is an indicative number that may also represent more elements that cannot be shown in a cross section view. Each segment 140 accounts for a respective individual voltage signal at output 142, as described below. An example top view of segments is shown in FIGS. 3A and 3B described below.

FIG. 1B is a partial zoom out of wafer inspection system 100 shown in FIG. 1A. FIG. 1B illustrates a group of three conversion circuits within conversion stage 136, each conversion circuit indicated by reference numeral 148. Conversion stage 136 comprises four such groups, each connected to a respective segment 140 through part of wires 132. A group 148 of conversion circuits are respectively connected to the group of three APD elements in segment 140 that is shown in FIG. 1B, such that each conversion circuit 148 converts the current produced by an APD element to a respective voltage output signal at the output of that conversion circuit. In the described embodiment, each conversion circuit 148 comprised a transimpedance amplifier (TIA). In other embodiments other conversion circuit types may be employed.

Conversion circuits 148 are followed by a summation arrangement 152 comprising an operational amplifier 156 that receives the voltage output signals produced by conversion circuits 148 through respective resistors 160. A feedback resistor 164 then determines the voltage level at the output of summation arrangement 152. This output voltage thus constitutes a summation signal which provides a summation result indicative of the overall radiation absorbed by segment 140 shown in FIG. 1B. It follows from the above that conversion stage 136 produces, through output 142, four summation signals, each related to a different segment 140. In some embodiments other summation arrangement are employed such as a digital processing unit, which first converts the output signals of conversion circuits 148 to digital values and then sums them numerically. In typical embodiments, the digital processing unit is implemented in hardware, software or a combination thereof.

The motivation for producing summation signals, as explained above, is to improve the Signal to Noise Ratio (SNR) at output 142, assuming that most of the noise is a readout noise resulting due to the input noise of conversion circuits 148 rather than shot noise of photodiodes 130. This improvement can be explained, with reference to FIG. 1B, by comparing between the resulting SNR related to segment 140 in the following two cases:

(A) Segment 140 consists of a single photodiode element connected to a single conversion circuits 148 (this case is not shown in FIGS. 1A and 1B).

(B) Segment 140 is split to three electrically inter-isolated radiation-sensitive elements 130 as shown in FIG. 1B.

Let us assume that the SNR in case A is V/N where V stands for the area of segment 140 and N stands for Noise Intensity (N may be calculated, for example, as the Root of Sum of Squares (RSS) value) of the current collected by segment 140. Let us calculate now the SNR in case B. As the desired signal is proportional to the area of segment 140, it is not meaningfully affected by the split and therefore it is equal to V. However, the capacitance of each photodiode element 130 is ⅓ of the capacitance of segment 140 since a photodiode capacitance is proportional to the photodiode area. Consequently, the noise voltage at the output of each conversion circuits 148 is (⅓)*N. The noise voltage at the output of summation arrangement 152 is the rout-mean-square of the noise at the outputs of the three conversion circuits 148, i.e. (1/√3)*N. Hence the SNR in case B is √3*V/N, i.e. √3 higher than in case A. In the general case the resulting SNR is Aix higher, where X is the number of elements per segment.

The radiation-sensitive elements 130 may share a common support surface, for example, a ceramic substrate. The radiation-sensitive elements 130 may be placed adjacently to each other, up to a physical touch. In such an adjacent placement of the radiation-sensitive elements 130, the radiation is collected in a continuous manner across the radiation-sensitive surface.

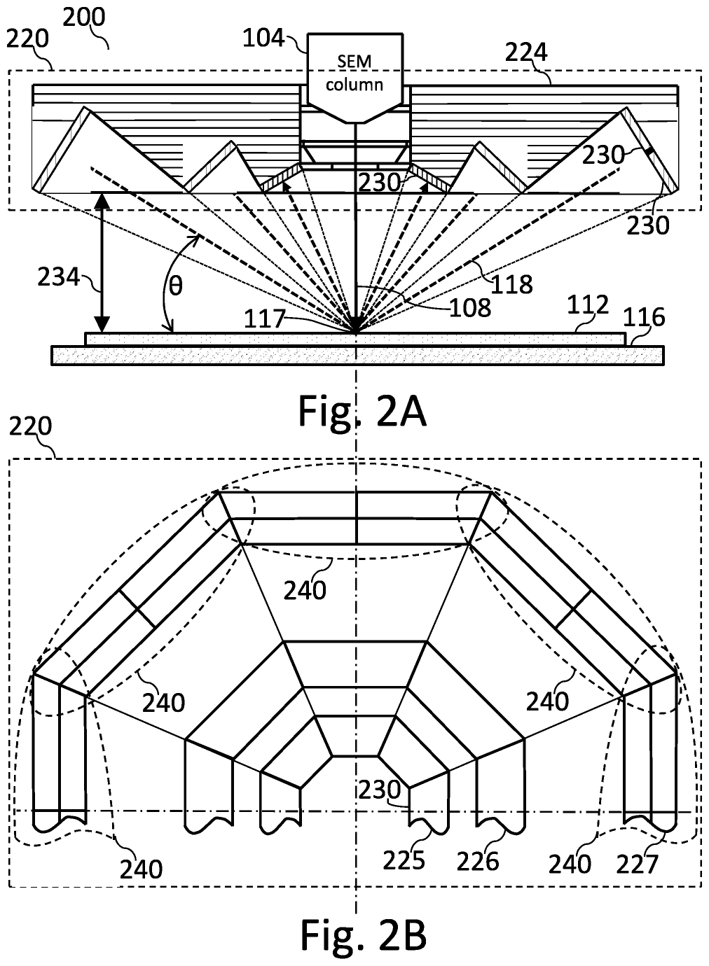

FIGS. 2A and 2B depict two views of a multiplane radiation-sensitive device 220 which is part of a wafer inspection system 200, in accordance with an embodiment of the present invention. FIG. 2A depicts a cross-sectional side view and FIG. 2B depicts a bottom view. The following explanations relate to FIGS. 2A-2B together. In the following, only device 220 is described since the rest of system 200 was already included in FIG. 1A. Device 220 comprises a ceramic substrate 224, which constitutes a support arrangement for an array of electrically inter-isolated radiation-sensitive elements 230. In the side of ceramic substrate 224 that faces inspected surface 112 there are three concentric octagonally shaped grooves 225, 226, 227, each comprising eight inclined planes directed to incidence point 117. In other embodiments, different groove numbers and shapes may be realized. Electrically inter-isolated photodiode elements 230, which are principally the same as photodiodes 130 in in FIG. 1A, are mechanically attached to the inclined planes in ceramic substrate 224 (only part of elements 230 are indicated by reference numeral for the sake of drawing clarity). As a result, all elements 230 are directed toward incidence point 117, which thereby constitute a focal point in the sense that radiation 118 impinges on elements 230 substantially perpendicularly.

The elements 230 attached to any groove side constitute a contiguous radiation-sensitive plane. In device 220, the planes of grooves 225 and 226 are one element planes. Each of the eight planes of groove 227 comprises a contiguous radiation-sensitive segment of device 220 comprising four elements 230, indicated in FIG. 2B by a dashed ellipse 240.

In the described embodiment, all the elements in each plane 240 are coupled through conversion circuits, such as circuit 148, to a summation arrangement, such as arrangement 152, for improving the detection SNR as explained above with regard to FIGS. 1A and 1B. The rational for this is the following: The planes disposed farther from point 117 are of larger area and receive lower radiation density. Consequently the dominant noise affecting the SNR while detecting their received radiation in readout noise, the SNR is typically low and their larger area allows partitioning to several elements. In other embodiments segments 230 may comprise part of a plane or several planes. The geometrical and spatial arrangement of the planes may be set to collect radiation in predetermined collection angles.

As shown in FIG. 2A, ceramic substrate 224 is formed such that the angle θ between the normal to a radiation-sensitive plane and the inspected surface is inversely proportional to the length of said normal. This is done so as to keep the Working Distance operational parameter at acceptable value. The shortest distance between each plane and the inspected surface equal to or greater than a predefined Working Distance indicated in FIG. 2A by reference numeral 234. In the example of FIG. 2A, the radiation sensitive device 220 is illustrated as the lower part of the SEM column, and thus the Working distance is shown as reflecting the distance between the wafer 112 and device 220.

The Working Distance in SEM is the distance from the lower SEM lens to the inspected object at which the beam is focused. For various applicational requirements, the Working Distance needs to be minimized. For certain applications, the radiation sensitive array must have certain thickness and this requirement may limit the ability to minimize the Working Distance.

According to an embodiment of the invention, the radiation-sensitive surface is shaped as a dome-shape surface. The Forming of the radiation-sensitive surface as a dome-shaped surface would allow high sensor response for low collection angles; however, implementing a dome-shaped surface would require thicker carrying substrate. While in general, thicker carrying substrate may be useful, there are certain operational constrains that require thinner carrying substrate. For example, for certain SEM imaging applications, the Working Distance operating parameter (illustrated by numerical reference 234 in FIG. 2A) is impacting the imaging resolution. Higher resolution may require shorter Working Distance.

The structure illustrated in FIG. 2A allows for achieving high sensor response, while using limited radiation-sensitive device′ thickness. The structure illustrated in FIG. 2A allows for efficient collection of signals at low radiation angles.

According to yet another embodiment of the invention, radiation sensitive device with thicker substrate can be used. For example, the radiation sensitive device 220 may be aligned with the bottom part of SEM column 104 or be set at a higher distance from the wafer 112.

FIG. 3A illustrates a top view of a radiation-sensitive device 320a, which is part of a wafer inspection system (not shown in FIG. 3A) like those shown in the previous figures. Radiation-sensitive device 320a comprises an arrangement of four individually cut sections 325a, 325b, 325c and 325d. A collection of section sides, one of each section, forms a square opening 326a in radiation-sensitive device 320a, which allows radiation to pass through. In other embodiments other polygonal shapes of opening 326a are formed, by employing various segment numbers and by using unequal edge sizes. Each section comprises multiple electrically inter-isolated photodiode elements 330. Each dashed ellipse 340 indicates a segment comprising two elements, which would yield a summation signal at the system output, as explained with regard to the previous FIGs. In other embodiments, other figures and shapes of element per segment are employed. The figures and shapes of element per segment may not be uniform over the same radiation-sensitive sections. In some embodiments the radiation-sensitive surface of at least part of sections 325a to 325d is formed to have a plurality of planes all directed to the same focal points as described above with regard to FIGS. 2A and 2B. In other embodiments, sections 325a, 325b, 325c and 325d are inclined such that a dome-shape structure is realized.

FIG. 3B illustrates a top view of a radiation-sensitive device 320b, which differs from radiation-sensitive device 320a in that it comprises only three sections 325a, 325b and 325c. Consequently, the created opening 326b has a partial polygon shape.

The realization of a dome-shape device may require the use of a support arrangement to which the radiation-sensitive elements are mechanically attached. For example, the support arrangement may comprise a ceramic substrate. The realization of the dome-shape device is presented herein as integrated with the electrical segmentation of the radiation-sensitive elements, each with its conversion circuit and with a summation arrangement. The dome shape device may be realized without the electrical segmentation of the of the radiation-sensitive elements. Further, the dome shape device may be realized by the use of spaced-apart radiation-sensitive elements.

The above description has focused on the specific system and device components that are essential for understanding certain features of the disclosed techniques. Conventional components that are not needed for this understanding have been omitted from FIGS. 1A to 3B for the sake of simplicity but will be apparent to persons of ordinary skill in the art. The configurations shown in FIGS. 1A to 3B are example configurations, chosen purely for the sake of conceptual clarity. In alternative embodiments, any other suitable configurations can also be used. For example, in some embodiments, radiation-sensitive devices as described above may comprise several openings, in various locations on the radiation-sensitive device, for allowing irradiation by more than a single primary beam and/or for detecting reflected radiation in separate radiation-sensitive devices. In some embodiments, radiation-sensitive devices may be employed that comprise any type of radiation-sensitive elements, as well as different element types in the same radiation-sensitive device.

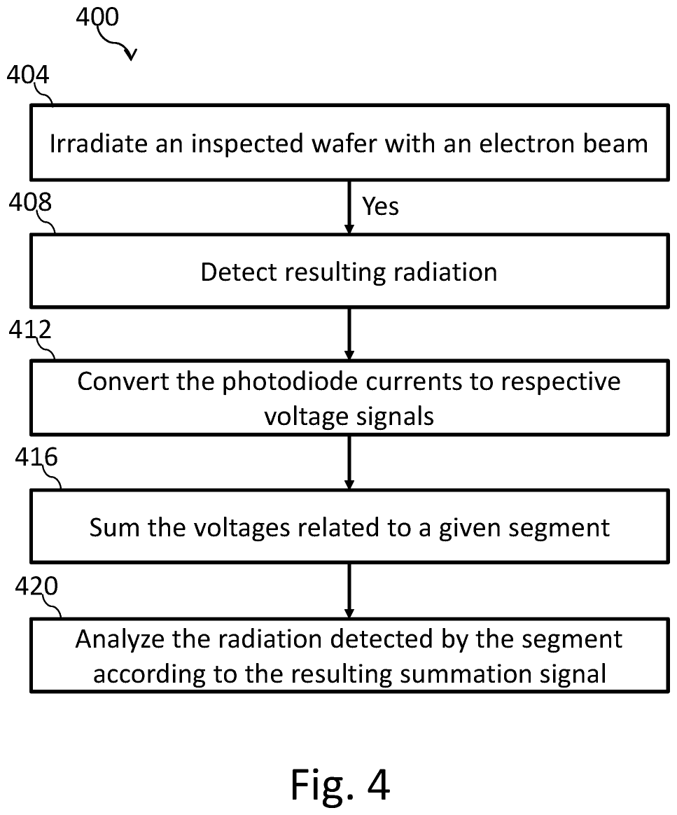

FIG. 4 is a flowchart 400 that schematically illustrates a method for reducing noise in a wafer inspection system, in accordance with an embodiment of the present invention. The method begins with an irradiating step 404, in which a primary electron beam 108 emitted from SEM column 104 irradiates an object 112 under evaluation, which is, in an embodiment, a semiconductor wafer under inspection. In a detecting step 408 that follows, a radiation-sensitive segment such as 140, 240, and 340, of a radiation-sensitive device such as 120, 220, 320a and 320b, comprising several adjacent electrically inter-isolated photodiode elements such as 130, 230, and 330, absorbs resulting radiation that emanates from object 112. Next, in a converting step 412, conversion circuits 148 convert the currents produced by the photodiode elements due to detecting the emanated radiation, to respective voltage signals.

The method proceeds to a summing step 416, in which summation arrangement 152 produces a summation signal, which is approximately proportional to the radiation emanating from object 112 and detected by the radiation-sensitive segment. Flowchart 400 ends with an analyzing step, in which a processing stage that follows summation arrangement 152 analyzes and/or evaluates the summation signal.

Flowchart 400 is an example flowchart, which was chosen purely for the sake of conceptual clarity. In alternative embodiments, any other suitable flowchart can also be used for illustrating the disclosed method. Method steps that are not mandatory for understanding the disclosed techniques were omitted from FIG. 3 for the sake of simplicity.

Although the embodiments described herein mainly address semiconductor wafers inspection systems, the methods and systems exemplified by these embodiments can also be applied to systems that comprise any suitable type of particle and wave radiation, and to any suitable application that involves radiation detection such as imaging and viewing.

It will thus be appreciated that the embodiments described above are cited by way of example, and that the present invention is not limited to what has been particularly shown and described hereinabove. Rather, the scope of the present invention includes both combinations and sub-combinations of the various features described hereinabove, as well as variations and modifications thereof which would occur to persons skilled in the art upon reading the foregoing description and which are not disclosed in the prior art.

What is claimed is:

1. A device for detecting radiation, the device comprising:
a radiation-sensitive surface comprising an array of electrically inter-isolated radiation-sensitive elements, wherein each radiation-sensitive element in the array of electrically inter-isolated radiation-sensitive elements generates an electric current in response to absorbing radiation;
an array of conversion circuits, wherein each conversion circuit in the array of conversion circuits is electrically coupled to a respective radiation-sensitive element in the array of electrically inter-isolated radiation-sensitive elements and is configured to generate an output signal indicative of the current generated by the radiation-sensitive element coupled thereto; and
one or more summation arrangements, wherein each summation arrangement in the one or more summation arrangements is coupled to a respective group of the conversion circuits and configured to produce a summation result indicative of the radiation absorbed by respective group of the conversion circuits.

2. The device of claim 1 wherein the radiation-sensitive elements are formed of one or more of a group consisting of: avalanche photodiodes (APDs), PIN diodes, and scintillation sensors.

3. The device of claim 1 wherein each conversion circuit comprises a transimpedance amplifier.

4. The device of claim 1 wherein the summation arrangement comprises a digital processing unit.

5. The device according to claim 1 wherein the device is arranged with one or more openings configured for allowing radiation to pass through the one or more openings.

6. The device according to claim 1 wherein the radiation-sensitive surface is shaped as a dome-shape surface.

7. The device according to claim 1 wherein different radiation-sensitive elements are associated with different radiation-sensitive planes such that all of the radiation-sensitive elements are directed toward a focal point on an inspected surface, an angle between a normal to a radiation-sensitive plane and the inspected surface is inversely proportional to the length of said normal, and the shortest distance between each radiation-sensitive plane and the inspected surface is equal to or greater than a preconfigured minimum working distance.

8. A device according to claim 1 further comprising a support arrangement to which the array of electrically inter-isolated radiation-sensitive elements are mechanically attached and wherein the radiation-sensitive elements are arranged adjacent to each other, spaced-apart from each other, or a combination thereof.

9. A device for detecting radiation emanated from an inspected surface, the device comprising:
an array of electrically inter-isolated radiation-sensitive elements that form a radiation-sensitive surface and disposed to form an array of radiation-sensitive planes with each radiation-sensitive plane in the array of radiation-sensitive planes comprising one or more radiation-sensitive elements; and
a support arrangement to which the radiation-sensitive elements are mechanically attached,
wherein the support arrangement is structured such that all the radiation-sensitive elements in the array of electrically inter-isolated radiation-sensitive elements are directed toward a focal point on the inspected surface with an angle between the normal to a radiation-sensitive plane and the inspected surface being inversely proportional to the length of said normal and the shortest distance between each radiation-sensitive plane and the inspected surface being equal to or greater than a preconfigured minimum working distance.

10. The device of claim 9 having at least one traversing opening which is formed to allow radiation to pass therethrough toward the focal point, thereby allowing a responsive radiation to emanate therefrom toward the radiation-sensitive elements.

11. The device of claim 9 wherein each radiation-sensitive element in the array of electrically inter-isolated radiation-sensitive elements is adapted to generate an electric current in response to absorbing radiation, and the device further comprises:
an array of conversion circuits, wherein each conversion circuit in the array of conversion circuits is electrically coupled to a respective radiation-sensitive element and configured to generate an output signal indicative of the current generated by the radiation-sensitive element coupled thereto; and
at least one summation arrangement coupled to a group of the conversion circuits in the array of conversion circuits, wherein the conversion circuits that belong to said group are electrically coupled to radiation-sensitive elements that constitute a contiguous segment of the radiation-sensitive surface, said segment comprising either a part of a radiation-sensitive plane or a plurality of radiation-sensitive planes, said summation arrangement configured to produce a summation result indicative of the whole radiation absorbed by said segment.

12. The device of claim 9 wherein the inspected surface comprises one of a semiconductor wafer and a mask.

13. The device of claim 9 wherein the support arrangement comprises a ceramic substrate.

14. The device of claim 9 wherein the radiation-sensitive elements type is at least one of avalanche photodiode (APD), PIN diode and scintillation sensor.

15. An arrangement of individually cut radiation-sensitive sections forming together a radiation-sensitive surface, wherein a collection of section sides, one of each section, forms an opening in the radiation-sensitive surface having either a partial or a complete polygon shape.

16. The arrangement of claim 15 wherein said opening is formed to allow radiation to pass therethrough toward an object under evaluation so as to result in responsive radiation to emanate from said object under evaluation toward the radiation-sensitive surface.

17. The arrangement of claim 15 wherein at least one of the radiation-sensitive sections comprises an array of electrically inter-isolated radiation-sensitive elements each adapted to generate an electric current in response to absorbing radiation, the arrangement further comprising:
an array of conversion circuits, wherein each conversion circuit in the array of conversion circuits is electrically coupled to a respective radiation-sensitive element and configured to generate an output signal indicative of the current generated by the radiation-sensitive element coupled thereto; and
at least one summation arrangement coupled to a group of the conversion circuits in the array of conversion circuits, wherein the conversion circuits that belong to said group are electrically coupled to radiation-sensitive elements that constitute a contiguous segment of the at least one radiation-sensitive section, said summation arrangement configured to produce a summation result indicative of the whole radiation absorbed by said segment.

18. The arrangement of claim 17 wherein the object under evaluation comprises an inspected surface and at least one of the radiation-sensitive sections comprises an array of electrically inter-isolated radiation-sensitive elements that are disposed to form an array of radiation-sensitive planes wherein each radiation-sensitive plane comprises one or more radiation-sensitive elements, said at least one of the radiation-sensitive sections further comprises a support arrangement to which the radiation-sensitive elements are mechanically attached, and wherein the support arrangement is structured such that all the radiation-sensitive elements are directed toward a focal point on the inspected surface, an angle between the normal to a radiation-sensitive plane and the inspected surface is inversely related to the length of said normal to the radiation-sensitive plane, and the shortest distance between each radiation-sensitive plane and the inspected surface is equal to or greater than a preconfigured minimum working distance.

19. A method for reducing noise in an inspection system, comprising:
irradiating an inspected surface with one or more electron beams;
detecting, by a segmented radiation-sensitive surface composed of an array of electrically inter-isolated radiation-sensitive elements, radiation emanating from the inspected surface in response to the irradiating;
converting, by an array of conversion circuits, each conversion circuit electrically coupled to a respective radiation-sensitive element, the currents produced by the radiation-sensitive elements due to detecting the emanated radiation, to respective voltage signals;
producing, by one or more summation arrangements coupled to a respective group of the conversion circuits, a summation result indicative of the radiation absorbed by respective group of the conversion circuits; and
analyzing the radiation detected by the segmented radiation-sensitive surface according to the resulting summation signal.
